(19) United States
(12) Patent Application Publication
(10) Pub. No.: US 2017/0309817 A1
(43) Pub. Date: Oct. 26, 2017

(54) VARIABLE-RESISTANCE ELEMENT AND METHOD OF MANUFACTURING VARIABLE-RESISTANCE ELEMENT AND SEMICONDUCTOR DEVICE

(71) Applicant: NEC Corporation, Minato-ku, Tokyo (JP)

(72) Inventors: Toshitsugu SAKAMOTO, Tokyo (JP); Munehiro TADA, Tokyo (JP)

(73) Assignee: NEC Corporation, Minato-ku, Tokyo (JP)

(21) Appl. No.: 15/523,435

(22) PCT Filed: Nov. 18, 2015
(86) PCT No.: PCT/JP2015/005766

§ 371 Date: May 1, 2017

(30) Foreign Application Priority Data
Nov. 25, 2014 (JP) 2014-237452

(51) Int. Cl. H01L 45/00

(52) U.S. Cl. CPC H01L 45/1266; H01L 45/1608; H01L 45/1273; H01L 45/08; H01L 45/1233; H01L 45/1616; H01L 45/1625; H01L 45/146

(57) ABSTRACT

The objective of the present invention is to make it possible to manufacture, with a high yield, a metal deposition type variable-resistance element with which variability of a program voltage and a leakage current under a high resistance state is reduced, while the program voltage is reduced. This variable-resistance element comprises: a first electrode which is embedded in a first insulating film and which supplies metal ions, an upper surface of the first electrode being exposed out of the first insulating film by means of an opening portion in a second insulating film covering the first insulating film; a metal deposition type variable-resistance film which covers the opening portion and is in contact with the upper surface of the first electrode; and a second electrode in contact with the upper surface of the variable-resistance film. The width of the opening portion is greater than the width of the upper surface of the first electrode, and the edge portions of the opening portion are provided in such a way that there is a margin between the edge portions of the opening portion and the edge portions of the upper surface of the first electrode which face the edge portions of the opening portion.

### TECHNICAL FIELD

The present invention relates to a metal disposition type variable-resistance element using metal ion transfer and electrochemical reaction and a semiconductor device using the same.

### BACKGROUND ART

A variable-resistance element using metal ion transfer and electrochemical reaction in a variable-resistance film includes three layers; a copper electrode, a variable-resistance film, and an inert electrode. The copper electrode serves not only as an electrode, but also to supply a metal ion to the variable-resistance film. A material of the inert electrode is a metal which does not supply a metal ion to the variable-resistance film. The term inert electrode means an electrode that does not contribute to reaction. When the copper electrode is grounded and a negative voltage is applied to the inert electrode, a metal of the copper electrode is converted into a metal ion and is dissolved in the variable-resistance film. Then, the metal ion in the variable-resistance film is precipitated into the variable resistance film as a metal and the precipitated metal forms a metal-bridge that connects the copper electrode and the inert electrode. By electrically connecting the copper electrode and the inert electrode with the metal-bridge, the variable-resistance element is translated from a high-resistant state to a low-resistant state.

In contrast, when the copper electrode of the variable-resistance element in the low-resistant state described above is grounded and a positive voltage is applied to the inert electrode, the metal-bridge is dissolved in the variable-resistance film, and part of the metal-bridge is broken. Accordingly, electric connection between the copper electrode and the inert electrode by the metal-bridge is broken, and thus the variable-resistance element is returned to the high-resistant state. The electric characteristics may be varied such that the resistance between the copper electrode and the inert electrode increases or an interelectrode capacitance varies from a stage before the electric connection is completely broken, and finally the electric connection therebetween is broken. In order to achieve translation from the high-resistant state to the low-resistant state described above, a negative voltage may be applied again to the inert electrode.

Using the variable-resistance element in a wiring changeover switch in a programmable device is proposed in NPL 1. By using the variable-resistance element, not only a reduction of a switching area to 1/30 of switches of other types and a reduction of a switching resistance to 1/40 of switches of other types, but also integration of the variable-resistance element into an interconnect layer are enabled. Therefore, reduction in chip area and improvement of the interconnect delay are expected.

Methods of manufacturing the variable-resistance element in an integrated circuit are disclosed in PTL 1 and PTL 2.

PTL 1 discloses a method of integrating a variable-resistance element in a copper multilayer interconnection. According to PTL 1, one copper interconnect out of the copper multilayer interconnection is assigned as a copper electrode of the variable-resistance element, so that the copper interconnect serves also as the copper electrode of the variable-resistance element. Accordingly, increase in density by miniaturizing the variable-resistance element is achieved and the number of steps may be simplified. The variable-resistance element may be mounted only by adding a process using two photomasks to a normal copper damascene interconnect process, so that a cost reduction may be simultaneously achieved. Furthermore, improvement of the device is achieved by mounting a variable-resistance element also in a leading-edge device composed of copper interconnect.

According to FIG. 3 of PTL 1, an opening portion that communicates with part of a first interconnect is formed by dry-etching an insulating barrier film, and variable-resistance element films are deposited so as to cover the exposed first interconnect. Subsequently, a first upper electrode and a second upper electrode are formed to achieve a configuration of the variable-resistance element.

PTL 2 also discloses a method of integrating a variable-resistance element in a copper multilayer interconnection. In FIG. 17 of PTL 2, an opening portion is provided in an insulating barrier film to expose part of an upper surface of the copper interconnect (first interconnects 5a, 5b), and a variable-resistance element film, a first upper electrode, and a second upper electrode are formed on the copper interconnect. Here, an opening portion is provided to expose one of ends of the copper interconnect, and the end and the variable-resistance element film are in contact with each other.

FIG. 14 illustrates a cross-sectional structure of the variable-resistance element disclosed in FIG. 11 of PTL 2. A first variable-resistance element includes a first copper interconnect 5a′, a variable-resistance film 9′, and an upper electrode 10′. A second variable-resistance element includes a first copper interconnect 5b′, the variable-resistance film 9′, and the upper electrode 10′. The first copper interconnects 5a′ and 5b′ are covered with barrier metals 6a′ and 6b′ except for upper surfaces thereof and are embedded in an interlayer insulating film 4′. The upper surfaces of the first copper interconnects 5a′ and 5b′ are covered with a barrier insulating film 7′, and are in contact with the variable-resistance film 9′ via an opening portion 26′ provided in the barrier insulating film 7′ (illustrated in FIG. 15).

The variable-resistance film 9′ covers the opening portion 26′ of the barrier insulating film 7′ and is partly in contact with an upper surface of the barrier insulating film 7′. The variable-resistance film 9′ is in contact with the upper electrode 10′. The upper electrode 10′ is in contact with a copper-made plug 19′ covered with a barrier metal 20′ on a surface thereof. The plug 19′ is in contact with a second copper interconnect 18′. The plug 19′ and the second copper interconnect 18′ are embedded in an interlayer insulating film 15′, and an upper surface of the second copper interconnect 18′ is covered with a barrier insulating film 21′.

FIG. 15 illustrates a cross-sectional view and a plan view of a step of opening the barrier insulating film 7′ for manufacturing a structure illustrated in FIG. 14. In the step of forming the opening portion 26′, a contact area between the variable-resistance film 9′ and the first copper interconnect 5a′ is preferably equivalent to a contact area between the variable-resistance film 9′ and the first copper interconnect 5b′.

Electric characteristics of the structure in FIG. 14 and a picture of the opening portion are disclosed in NPL 2. According to the electric characteristics of NPL 2, two sets of the variable-resistance elements are referred to as a complementary atom switch (CAS), and high OFF time reliability while reducing a program voltage is achieved. The program voltage is a voltage appearing when the resistance of the variable-resistance element changes from the high-resistant state to the low-resistant state, and is preferably not higher than 2V. In the case where the variable-resistance element is applied to a programmable logic described in NPL 1, the resistance is required not to vary even when an operation voltage (1V, for example) of the integrated circuit is applied. In other words, OFF time reliability is required which ensures no variation to the low-resistant state even when a voltage of 1V, which corresponds to the operation voltage, is applied to the variable-resistance element in the high-resistant state for 10 years, which is a life of the integrated circuit. The complementary atom switch solves the subject described above by the following method.

The metal disposition type variable-resistance element is provided with a bipolar characteristic. A case is considered where two variable-resistance elements in the high-resistant state are connected in series in the opposite direction and a voltage is applied to both ends. As used herein the term “connected in series in an opposite direction” is intended to include connecting two inert electrodes or two copper electrodes of each variable-resistance element with each other. In FIG. 14, the upper electrode 10′, which corresponds to the inert electrode, is shared, that is, is connected. When a voltage is applied between both ends, that is, between the first copper interconnect 5a′ and the second copper interconnect 5b′, a voltage of a polarity which does not cause variation in resistance is applied to one of the two variable-resistance elements irrespective of the polarity of the voltage. In this configuration, it is reported that the high-resistant state may be maintained for 10 years or more even when applying 1V, which is the operation voltage of the integrated circuit (FIG. 16 in NPL 2).

It is also reported that when programming the elements connected in series, the resistance is varied at a low voltage on the order of 2V by applying a voltage independently to each of the variable-resistance elements (FIG. 9(a) in NPL 2). Contact of the ends of the first copper interconnect 5a′ and the first copper interconnect 5b′ with the variable-resistance film 9′ also contributes to reduction of a program voltage. The program voltage is lower in a structure illustrated in FIG. 14 in which the variable-resistance film is in contact with the ends of the copper interconnect than in a structure of PTL 1 (FIG. 1 in PTL 1) in which the variable-resistance film is in contact with a flat portion of the copper interconnect. At the ends of the copper interconnect, the shape of the copper is pointed. When the ends of the electrode are pointed, concentration of electric field may result. In other words, the electric field is intensified by the structure having the pointed ends, so that generation or transfer of a copper ion is activated, and a low program voltage is realized.

Techniques relating to the variable-resistance elements and semiconductor devices employing the same are also disclosed in PTL 3, PTL 4, PTL 5, PTL 6, and PTL 7.

### CITATION LIST

### Patent Literature

[PTL 1] WO No. 2010/079827
[PTL 2] WO No. 2011/158821
[PTL 3] JP-A-2008-244090
[PTL 4] JP-A-2012-094759
[PTL 5] JP-A-2013-084778
[PTL 6] WO No. 2007/091326
[PTL 7] WO No. 2012/042828

### Non Patent Literature

NPL 1: S. Kaeriyama, et al., “A nonvolatile Programmable Solid-Electrolyte Nanometer Switch”, IEEE JOURNAL OF SOLID-STATE CIRCUITS, VOL. 40, NO. 1, pp. 168-176, 2005.
NPL 2: M. Tada, T. Sakamoto, et al., “Highly Reliable, Complementary Atom Switch (CAS) with Low Programming Voltage Embedded in Cu BEOL for Nonvolatile Programmable Logic”, IEDM, Technical Digest, pp. 689-692, 2011.

### SUMMARY OF INVENTION

### Technical Problem

The program voltage also depends on a contact area between the copper interconnect and the variable-resistance film. The larger the contact area, the higher the probability that a copper bridge is connected, and thus the lower the program voltage. A leak current in the high-resistant state also depends on the contact area. From such circumstances, the contact areas between the copper interconnect and the variable-resistance film is required to be equal between the variable-resistance elements.

In a picture of the opening portion in FIG. 7 of NPL 2, the surface areas of upper surfaces of the two copper interconnects exposed through the opening portion are substantially equivalent. In this manner, in order to maintain the surface areas of the exposed copper interconnects constant, improvement of accuracy of lithography that determines the position of the opening portion is required. The accuracy at present is on the order of 10 nm to 50 nm. Therefore, when the width of the copper interconnect is reduced to 100 nm or lower, variations in surface areas of the copper interconnects exposed through the opening portion 26′ become obvious due to the positional shift of the opening portion 26′ as illustrated in FIG. 16. FIG. 16 illustrates a case where the opening portion 26′ is shifted leftward when facing toward the page. In association with miniaturization of the variable-resistance element, the effect of the shift is increased. Therefore, variations in program voltage or leak current in a high-resistant state become an issue.

In the techniques that are disclosed in PTL 1 to PTL 7 and in NPL 1 and NPL 2, no disclosure and suggestion relating to a structure and a method for solving such variations, so that reduction of variations in the program voltage and the leak current in the high-resistant state is not achieved.

In view of such a problem described above, it is an object of the present invention to manufacture a metal disposition type variable-resistance element in which variations in program voltage and leak current in a high-resistant state is reduced while reducing the program voltage with high yield.

### Solution to Problem

A variable-resistance element according to the present invention includes; a first electrode that supplies a metal ion, the first electrode being embedded in a first insulating film and having an upper surface exposed from the first insulating film through an opening portion of a second insulating film, the second insulating film covering the first insulating film; a metal disposition type variable-resistance film that covers the opening portion and comes into contact with an upper surface of the first electrode; and a second electrode that comes into contact with an upper surface of the variable-resistance film, in which the opening portion has a width larger than a width of the upper surface of the first electrode, and an end of the opening portion is provided with a margin from an end of the upper surface of the first electrode that the end of the opening portion opposes.

A method of manufacturing a variable-resistance element according to the present invention includes: forming a first electrode that is embedded in a first insulating film and supplies a metal ion; forming a second insulating film that covers the first insulating film and the first electrode; forming an opening portion in the second insulating film so as to expose an upper surface of the first electrode, the opening portion having the width larger than the width of the upper surface of the first electrode, and an end of the opening portion having a margin from an end of the upper surface of the first electrode that the end of the opening portion opposes; forming a metal disposition type variable-resistance film that covers the opening portion and comes into contact with the upper surface of the first electrode, and forming a second electrode that comes into contact with an upper surface of the variable-resistance film.

A semiconductor device according to the present invention includes the variable-resistance element according to the present invention built into a multilayer copper interconnect of a semiconductor integrated circuit that has the multilayer copper interconnect.

### Advantageous Effects of Invention

According to the present invention, a metal disposition type variable-resistance element in which variations in program voltage and leak current in a high-resistant state is reduced while reducing the program voltage may be manufactured with high yield.

### BRIEF DESCRIPTION OF DRAWINGS

FIG. 1 is a cross-sectional view illustrating a structure of a variable-resistance element according to a first example embodiment of the present invention.

FIG. 2 is a block diagram illustrating a configuration of a semiconductor device which employs the variable-resistance element according to the first example embodiment of the present invention.

FIG. 3 is a cross-sectional view illustrating a structure of a variable-resistance element according to a second example embodiment of the present invention.

FIG. 4 illustrates a cross-sectional view and a plan view for explaining the structure of the variable-resistance element according to the second example embodiment of the present invention.

FIG. 5 is a cross-sectional view for explaining the structure of the variable-resistance element according to the second example embodiment of the present invention.

FIG. 6A is a cross-sectional view illustrating a method of manufacturing the variable-resistance element according to the second example embodiment of the present invention.

FIG. 6B is a cross-sectional view illustrating the method of manufacturing the variable-resistance element according to the second example embodiment of the present invention.

FIG. 6C is a cross-sectional view illustrating the method of manufacturing the variable-resistance element according to the second example embodiment of the present invention.

FIG. 6D is a cross-sectional view illustrating the method of manufacturing the variable-resistance element according to the second example embodiment of the present invention.

FIG. 6E is a cross-sectional view illustrating the method of manufacturing the variable-resistance element according to the second example embodiment of the present invention.

FIG. 6F is a cross-sectional view illustrating the method of manufacturing the variable-resistance element according to the second example embodiment of the present invention.

FIG. 7 is a cross-sectional view illustrating a structure of a variable-resistance element according to a third example embodiment of the present invention.

FIG. 8 illustrates a cross-sectional view and a plan view for explaining the structure of the variable-resistance element according to the third example embodiment of the present invention.

FIG. 9 is a cross-sectional view illustrating a structure of a variable-resistance element according to a fourth example embodiment of the present invention.

FIG. 10 illustrates a cross-sectional view and a plan view for explaining the structure of the variable-resistance element according to the fourth example embodiment of the present invention.

FIG. 11A is a cross-sectional view illustrating a method of manufacturing the variable-resistance element according to the fourth example embodiment of the present invention.

FIG. 11B is a cross-sectional view illustrating the method of manufacturing the variable-resistance element according to the fourth example embodiment of the present invention.

FIG. 11C is a cross-sectional view illustrating the method of manufacturing the variable-resistance element according to the fourth example embodiment of the present invention.

FIG. 11D is a cross-sectional view illustrating the method of manufacturing the variable-resistance element according to the fourth example embodiment of the present invention.

FIG. 11E is a cross-sectional view illustrating the method of manufacturing the variable-resistance element according to the fourth example embodiment of the present invention.

FIG. 11F is a cross-sectional view illustrating the method of manufacturing the variable-resistance element according to the fourth example embodiment of the present invention.

FIG. 11G is a cross-sectional view illustrating the method of manufacturing the variable-resistance element according to the fourth example embodiment of the present invention.

FIG. 11H is a cross-sectional view illustrating the method of manufacturing the variable-resistance element according to the fourth example embodiment of the present invention.

FIG. 12 is a cross-sectional view illustrating a structure of a variable-resistance element according to a fifth example embodiment of the present invention.

FIG. 13 illustrates a cross-sectional view and a plan view for explaining a structure of a variable-resistance element of the fifth example embodiment of the present invention.

FIG. 14 is a cross-sectional view illustrating a structure of a variable-resistance element disclosed in PTL 2.

FIG. 15 illustrates a cross-sectional view and a plan view for explaining the structure of the variable-resistance element disclosed in PTL 2.

FIG. 16 is a plan view for explaining the structure of the variable-resistance element disclosed in PTL 2.

### DESCRIPTION OF EMBODIMENTS

Referring now to the drawings, example embodiments of the present invention will be described in detail. In the example embodiments described below, technically preferable limitations for implementing the present invention are provided. However, the scope of the invention is not limited to the description given below.

### First Example Embodiment

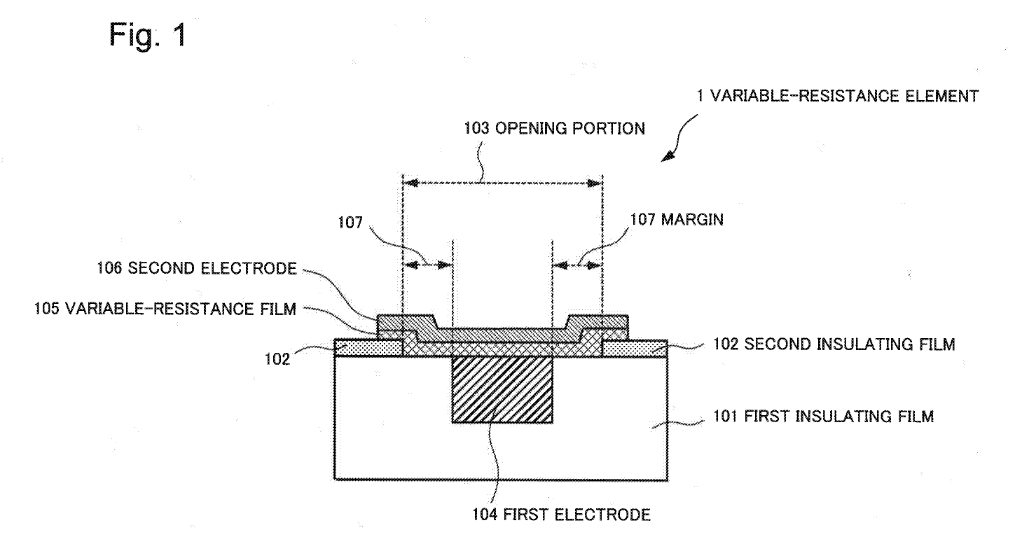

FIG. 1 is a cross-sectional view illustrating a structure of a variable-resistance element according to a first example embodiment of the present invention. A variable-resistance element 1 of the present example embodiment is embedded in a first insulating film 101 and includes a first electrode 104 that supplies a metal ion. An upper surface of the first electrode 104 is exposed from the first insulating film 101 through an opening portion 103 provided in a second insulating film 102 that covers the first insulating film 101. In addition, a metal disposition type variable-resistance film 105 that covers the opening portion 103 and is in contact with the upper surface of the first electrode 104 is provided. Furthermore, a second electrode 106 that comes into contact with an upper surface of the variable-resistance film 105 is provided. Furthermore, the width of the opening portion 103 is larger than the width of the upper surface of the first electrode 104, and ends of the opening portion 103 have a margin 107 from ends of the upper surface of the first electrode 104 that the ends of the opening portion 103 oppose.

A method of manufacturing the variable-resistance element 1 of the present example embodiment includes a step of forming the first electrode 104 embedded in the first insulating film 101 and configured to supply a metal ion, and a step of forming the second insulating film 102 that covers the first insulating film 101 and the first electrode 104. In addition, a step of forming the opening portion 103 that exposes the upper surface of the first electrode 104 in the second insulating film 102 is also included. At this time, the width of the opening portion 103 is larger than the width of the upper surface of the first electrode 104, and the ends of the opening portion 103 have the margin 107 from the ends of the upper surface of the first electrode 104 that the ends of the opening portion 103 oppose. In addition, a step of forming the metal disposition type variable-resistance film 105 that covers the opening portion 103 and is in contact with the upper surface of the first electrode 104, and a step of forming the second electrode 106 that is in contact with the upper surface of the variable-resistance film 105 are included.

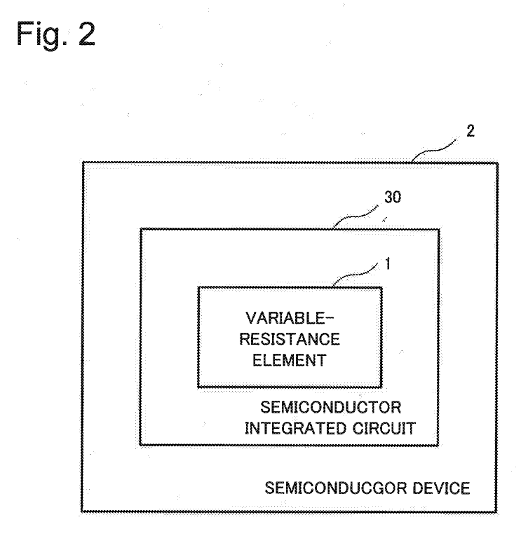

FIG. 2 is a block diagram illustrating a configuration of a semiconductor device which includes the variable-resistance element 1 of the present example embodiment built therein. The semiconductor device of the present example embodiment is a semiconductor device 2 having the variable-resistance element 1 built into a multilayer copper interconnect of a semiconductor integrated circuit 30 that has the multilayer copper interconnect.

According to the present example embodiment, a metal disposition type variable-resistance element in which variations in program voltage and leak current in a high-resistant state is reduced while reducing the program voltage may be manufactured with high yield.

### Second Example Embodiment

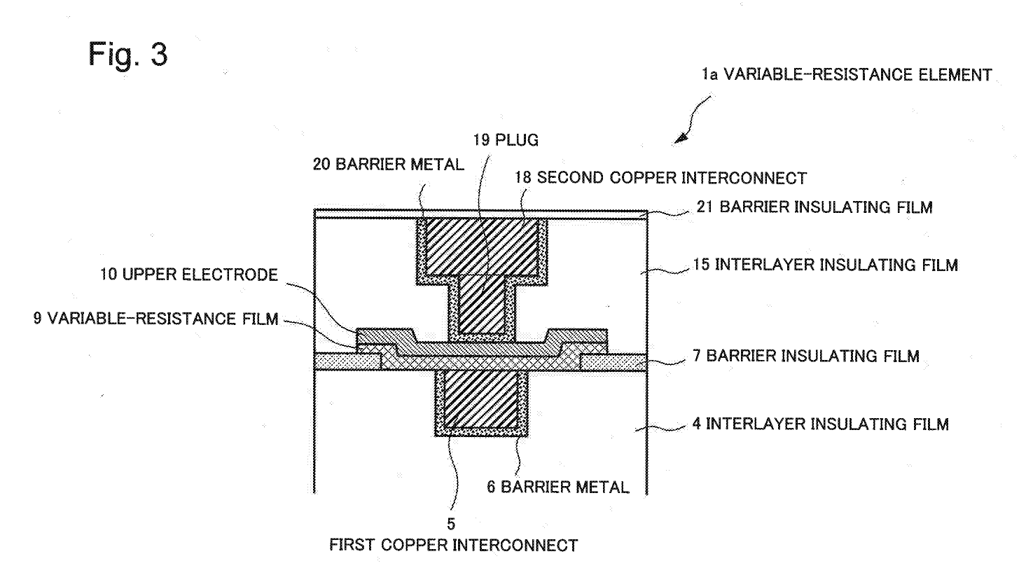

FIG. 3 is a cross-sectional view illustrating a structure of a variable-resistance element according to a second example embodiment of the present invention. A variable-resistance element 1a of the present example embodiment includes a first copper interconnect 5 which corresponds to an electrode that supplies a metal ion to a variable-resistance film 9, a barrier insulating film 7, the variable-resistance film 9, and an upper electrode 10, which is an inert electrode that does not supply a metal ion to the variable-resistance film 9.

The first copper interconnect 5 in the multilayer copper interconnect of the semiconductor integrated circuit is covered with a barrier metal 6 over side surfaces and a bottom surface, and is embedded in an interlayer insulating film 4. An upper surface of the first copper interconnect 5 is in contact with the variable-resistance film 9 via an opening portion of the barrier insulating film 7. The variable-resistance film 9 is in contact with the upper electrode 10. The upper electrode 10 is connected to a plug 19 covered with a barrier metal 20 over a bottom surface and side surfaces. The plug 19 is connected to a second copper interconnect 18. Side surfaces and a portion of a bottom surface, which is not in contact with the plug 19, of the second copper interconnect 18 are covered with the barrier metal 20. The second copper interconnect 18, the plug 19, the upper electrode 10, and the variable-resistance film 9 are embedded in an interlayer insulating film 15. The interlayer insulating film 15 and the second copper interconnect 18 are covered with a barrier insulating film 21.

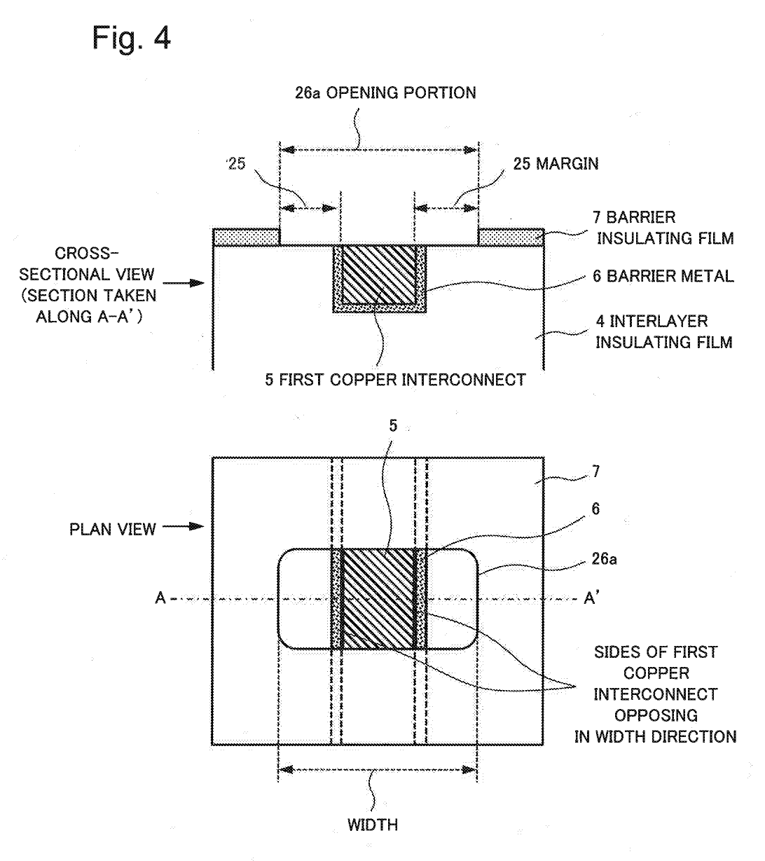

FIG. 4 illustrates a cross-sectional view (section taken along the line A-A′) and a plan view for explaining the position of an opening portion 26a in the barrier insulating film 7 of the variable-resistance element 1a. Part of the barrier insulating film 7 that covers the first copper interconnect 5 and the interlayer insulating film 4 is removed by etching to provide the opening portion 26a. The opening portion 26a is provided so as to expose part of the upper surface of the first copper interconnect 5 including both sides thereof opposing each other in a width direction of the first copper interconnect 5. At this time, the width of the opening portion 26a is larger than the width of the upper surface of the first copper interconnect 5. The opening portion 26a is provided so that ends of the opening portion 26a have a margin 25 from ends of the upper surface of the first copper interconnect 5 in the width direction that the ends of the opening portion 26a oppose. With the provision of the margin 25, even though the position of the opening portion 26a is shifted, the surface area of the exposed upper surface of the first copper interconnect 5 may be maintained constant.

If corners of the opening portion 26a are rounded in actual manufacturing steps, the margin 25 may be set to a size considering the roundness.

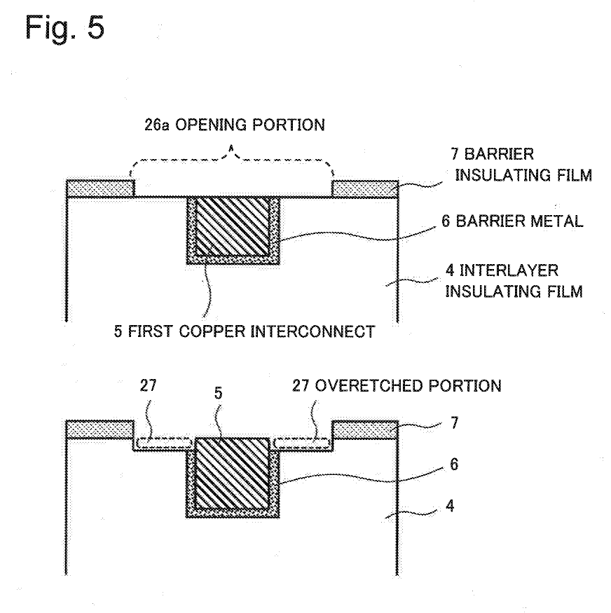

FIG. 5 is a cross-sectional view for explaining variations in the opening portion 26a of the variable-resistance element 1a. As illustrated in FIG. 5, when removing the opening portion 26a of the barrier insulating film 7 by etching, the interlayer insulating film 4 and the barrier metal 6 may be further etched to provide an overetched portion 27 and expose the side surfaces of the first copper interconnect 5. Exposure of the side surfaces of the first copper interconnect 5 provides a lower electrode having sharp-edged corners. When a voltage is applied to the first copper interconnect 5, electric field concentrates on the sharp-edged corners. With this structure, the program voltage may further be reduced.

The structure of the variable-resistance element 1a is fabricated by using the following materials.

The interlayer insulating film 4 is formed on a substrate (illustration is omitted) including a semiconductor device and the like such as a transistor formed on a silicon substrate by using semiconductor manufacturing steps. The interlayer insulating film 4 and the interlayer insulating film 15 may be formed of a compound of silicon and oxygen and, more preferably, are formed of a low-dielectric constant insulating film formed by adding a given amount of hydrogen, fluorine, or carbon to a compound of silicon and oxygen.

The barrier insulating film 7 and the barrier insulating film 21 are formed on the interlayer insulating film 4 including the first copper interconnect 5 and the interlayer insulating film 15 including the second copper interconnect 18, respectively. The barrier insulating film 7 and the barrier insulating film 21 have not only an effect of preventing oxidation of copper contained in the copper interconnect but also an effect of preventing the copper from diffusing into the interlayer insulating film during and after manufacture. For example, silicon carbide, silicon carbonitride, or silicon nitride, or a laminated structure thereof may be used as the barrier insulating film 7 and the barrier insulating film 21.

The barrier metal 6 and the barrier metal 20 may be formed of, for example, tantalum nitride or tantalum, or a laminated film thereof. The barrier metal 6 and the barrier metal 20 have an effect of preventing copper in the interconnect and the plug from diffusing into the interlayer insulating film. The thickness of tantalum nitride or tantalum may be on the order of 5 nm to 30 nm.

The material of the first copper interconnect 5 is a metal that is capable of supplying a metal ion into the variable-resistance film 9, and preferably is copper which is a material of the interconnect in the semiconductor integrated circuit. Preferably, the material of the plug 19 and the second copper interconnect 18 is copper.

The variable-resistance film 9 may be oxidized materials such as tantalum oxide or titanium oxide or calcogenide materials such as copper sulfide and silver sulfide. A switching element for programmable logic is preferably formed of an oxidized material, specifically, tantalum oxide. The reason why the oxidized material is suitable is that the voltage at the time of switching is higher than a logic voltage. In addition, the reason why tantalum oxide is preferable is that the tantalum oxide is highly reliable because the durable number of times of switching is 1000 times or more. The thickness of the variable-resistance film 9, which is an ion conducting layer, is preferably from 5 nm to 20 nm. The thickness of 5 nm or smaller causes a leak current when the power is OFF due to a tunnel current or a Schottky current. In contrast, the thickness of 20 nm or larger increases the switching voltage to 10V or higher, so that the required voltage is increased.

A metal which is less likely to be diffused or conduct an ion in the variable-resistance film 9 is used for the upper electrode 10. The upper electrode 10 is preferably formed of a metallic material having a smaller free energy of oxidation in absolute value than a metal component in the variable-resistance film 9 (for example, tantalum). For example, ruthenium, platinum, or ruthenium alloy may be used for the upper electrode 10.

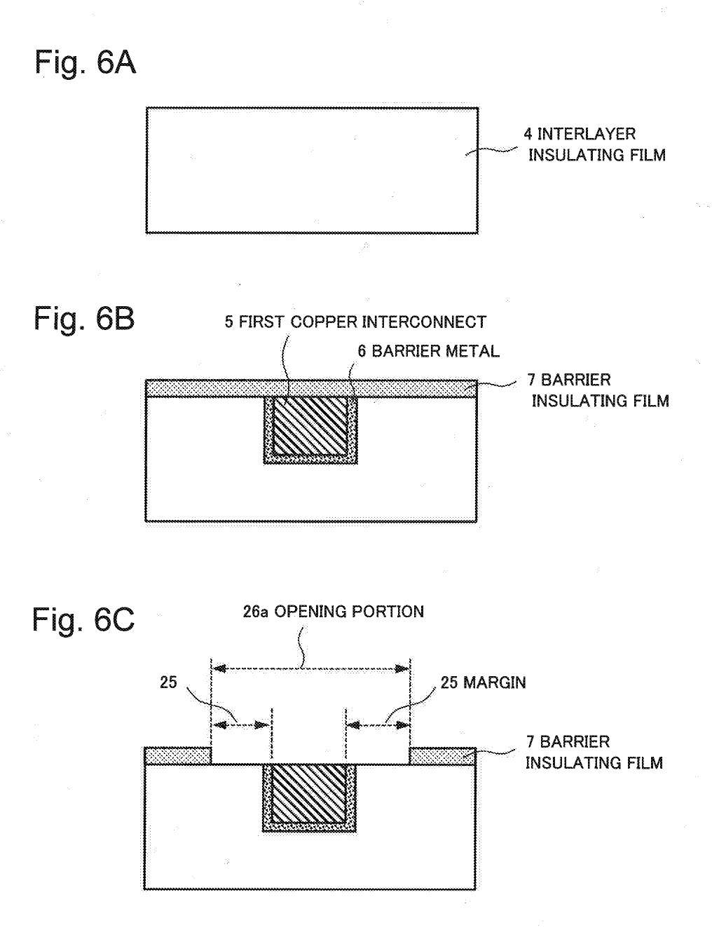

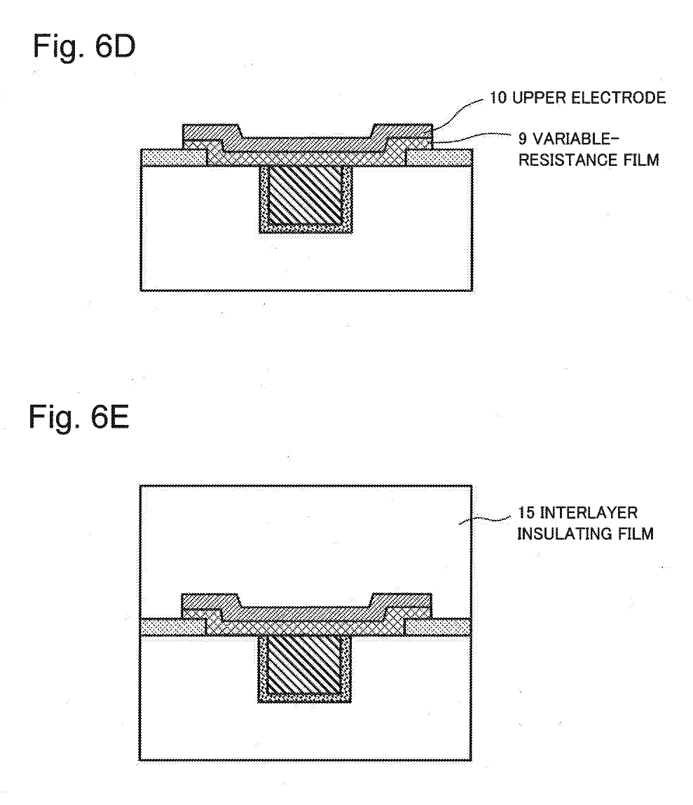

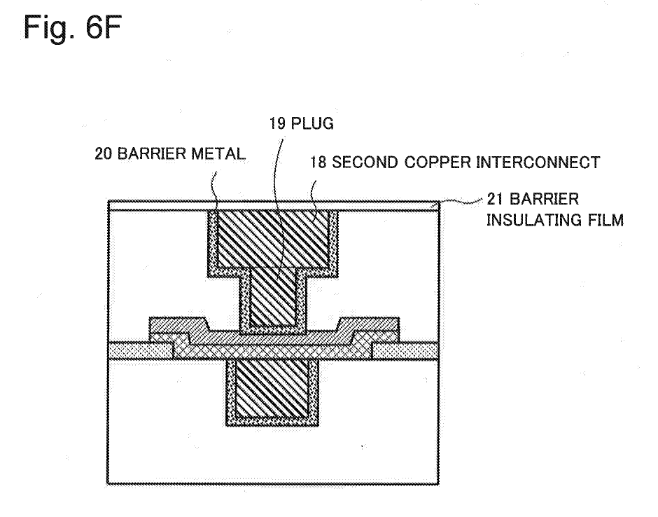

The structure of the variable-resistance element 1a may be fabricated by the following manufacturing steps (FIG. 6A to FIG. 6F).

[Step 1] (Forming Interlayer Insulating Film: FIG. 6A) A substrate (illustration is omitted) including a semiconductor device and the like such as a transistor formed on a silicon substrate by using the semiconductor manufacturing steps is prepared. A silicon nitride film is formed on the substrate as the interlayer insulating film 4 by Chemical Vapor Deposition (hereinafter, abbreviated as CVD) method.

[Step 2] (Forming Interconnect: FIG. 6B) An opening portion where the first copper interconnect 5 is to be embedded is formed in the interlayer insulating film 4 by using photolithography technique and etching technique. The barrier metal 6 and a copper seed layer are formed in the formed opening portion by the CVD method. The barrier metal 6 may be tantalum nitride having a thickness of 10 nm. The copper seed layer has a thickness on the order of 10 nm to 100 nm, and a small amount of impurity such as aluminum is added to be contained therein. Subsequently, electrolytic plating of copper is performed on the copper seed layer. The thickness of copper may be on the order of 800 nm to 1200 nm. Subsequently, useless parts of barrier metal and copper outside of the opening portion are removed away by Chemical Mechanical Polishing (hereinafter, referred to as CMP) method.

Furthermore, silicon carbonitride having a thickness of 50 nm is formed as the barrier insulating film 7 that covers the interlayer insulating film 4, the first copper interconnect 5, and the barrier metal 6 by a sputtering method or the CVD method.

Furthermore, thermal treatment is performed to cause the impurity in the copper seed layer to be diffused over the entire part of the first copper interconnect 5. By the thermal treatment, electromigration resistance of the first copper interconnect 5 is improved. Since the first copper interconnect 5 and the barrier metal 6 are covered with the barrier insulating film 7, oxidation of copper contained in the copper interconnect during the thermal treatment may be prevented, and manufacturing yield may be increased.

[Step 3] (Opening Barrier Insulating Film: FIG. 6C) The opening portion 26a of the barrier insulating film 7 is formed by using the photolithography technique and the etching technique. The opening portion 26a is provided so as to expose part of the upper surface of the first copper interconnect 5 including both sides thereof opposing each other in the width direction of the first copper interconnect 5. At this time, the width of the opening portion 26a is larger than the width of the upper surface of the first copper interconnect 5. The opening portion 26a is provided so that the ends of the opening portion 26a have a margin 25 from the ends of the upper surface of the first copper interconnect 5 in a width direction that the ends of the opening portion 26a oppose. With the provision of the margin 25, even though the position of the opening portion 26a is shifted, the surface area of the exposed upper surface of the first copper interconnect 5 may be maintained constant, and thus the manufacturing yield may be increased.

Causes of the positional shift of the opening portion 26a involve accuracy of photolithography when determining the position of the opening portion 26a. Therefore, the margin 25 is preferably set at least to a range within which accuracy of the photolithography is ensured. As used herein the term “accuracy of photolithography” is intended to include accuracy of registration of an exposing machine such as a stepper. If the corners of the opening portion 26a are rounded in the manufacturing steps, the margin 25 may be set to a size considering the roundness.

[Step 4] (Forming Variable-Resistance Film and Upper Electrode: FIG. 6D) Tantalum oxide having a thickness of 15 nm is formed as the variable-resistance film 9 and ruthenium having a thickness of 50 nm is formed as the upper electrode 10 by a sputtering method or the CVD method. By using the photolithography technique and the etching technique, the variable-resistance film 9 and the upper electrode 10 are processed into a shape that covers the opening portion 26a and also covers part of the barrier insulating film 7.

[Step 5] (Forming Interlayer Insulating Film: FIG. 6E) A silicon oxide film is formed as the interlayer insulating film 15 by the CVD method. Here, a level difference exists on the surface of the silicon oxide film due to level differences of the variable-resistance film 9 and the upper electrode 10, the level difference is flattened by the CMP method. The thickness of the interlayer insulating film 15 may be on the order of 600 nm.

[Step 6] (Forming Connection Plug and Interconnect: FIG. 6F) An opening portion where the plug 19 and the second copper interconnect 18 are to be embedded is formed in the interlayer insulating film 15 by using the photolithography technique and the etching technique. The barrier metal 20 and the copper seed layer, which corresponds to part of the copper, are formed in the formed opening portion by the sputtering method or the CVD method. The barrier metal 6 may be tantalum nitride having a thickness of 10 nm. The thickness of the copper seed layer may be on the order of 10 nm to 100 nm. Subsequently, the copper plating is performed on the copper seed layer. The thickness of copper may be on the order of 800 nm to 1200 nm. Subsequently, useless part of the barrier metal and copper formed outside of the opening portion are removed away by the CMP method to form the plug 19 and the second copper interconnect 18. Next, silicon carbonitride having a thickness of 50 nm that corresponds to the barrier insulating film 21 is formed by the sputtering method or the CVD method.

In the manufacturing method described above, the material and the thickness of each layer may be changed within a range that ensures the function as the variable-resistance element.

The semiconductor device of the present example embodiment is a semiconductor device which includes the variable-resistance element 1a integrated therein. In other words, the variable-resistance element 1a is built in a multilayer copper interconnect of a semiconductor integrated circuit such as the programmable logic including a semiconductor element and the like such as a transistor formed on a silicon substrate by using the semiconductor manufacturing steps and having a multilayer copper interconnect. The semiconductor device may additionally have a package that protects the semiconductor integrated circuit.

According to the present example embodiment, a metal disposition type variable-resistance element in which variations in program voltage and leak current in a high-resistant state are reduced while reducing the program voltage may be manufactured with high yield.

### Third Example Embodiment

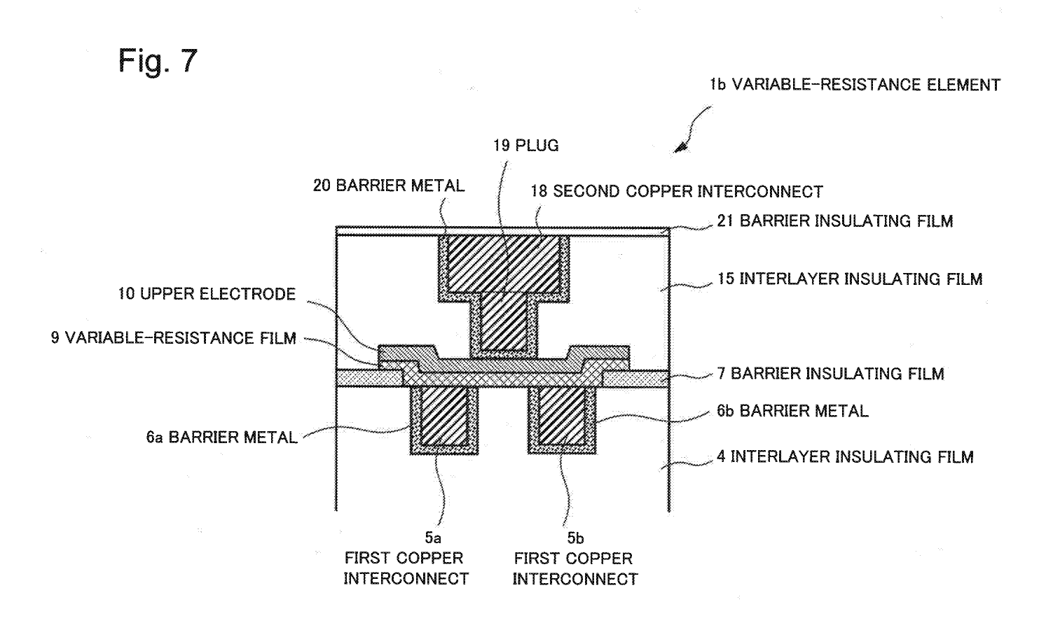

FIG. 7 is a cross-sectional view illustrating a structure of a variable-resistance element according to a third example embodiment of the present invention. A variable-resistance element 1b of the present example embodiment includes a first copper interconnect 5a and a first copper interconnect 5b each of which corresponds to an electrode that supplies a metal ion to the variable-resistance film 9, the barrier insulating film 7, the variable-resistance film 9, and the upper electrode 10, which is the inert electrode that does not supply a metal ion to the variable-resistance film 9.

The first copper interconnect 5a and the first copper interconnect 5b in the multilayer copper interconnect of the semiconductor integrated circuit are covered with a barrier metal 6a and a barrier metal 6b over side surfaces and bottom surfaces respectively, and are embedded in the interlayer insulating film 4. Upper surfaces of the first copper interconnects 5a and 5b are in contact with the variable-resistance film 9 via the opening portion of the barrier insulating film 7. The variable-resistance film 9 is in contact with the upper electrode 10. The upper electrode 10 is connected to the plug 19 covered with the barrier metal 20. The plug 19 is connected to the second copper interconnect 18. The side surface and a portion of the bottom surface, which is not in contact with the plug 19, of the second copper interconnect 18 are covered with the barrier metal 20. The second copper interconnect 18, the plug 19, the upper electrode 10, and the variable-resistance film 9 are embedded in the interlayer insulating film 15, and the interlayer insulating film 15 and the second copper interconnect 18 are covered with the barrier insulating film 21.

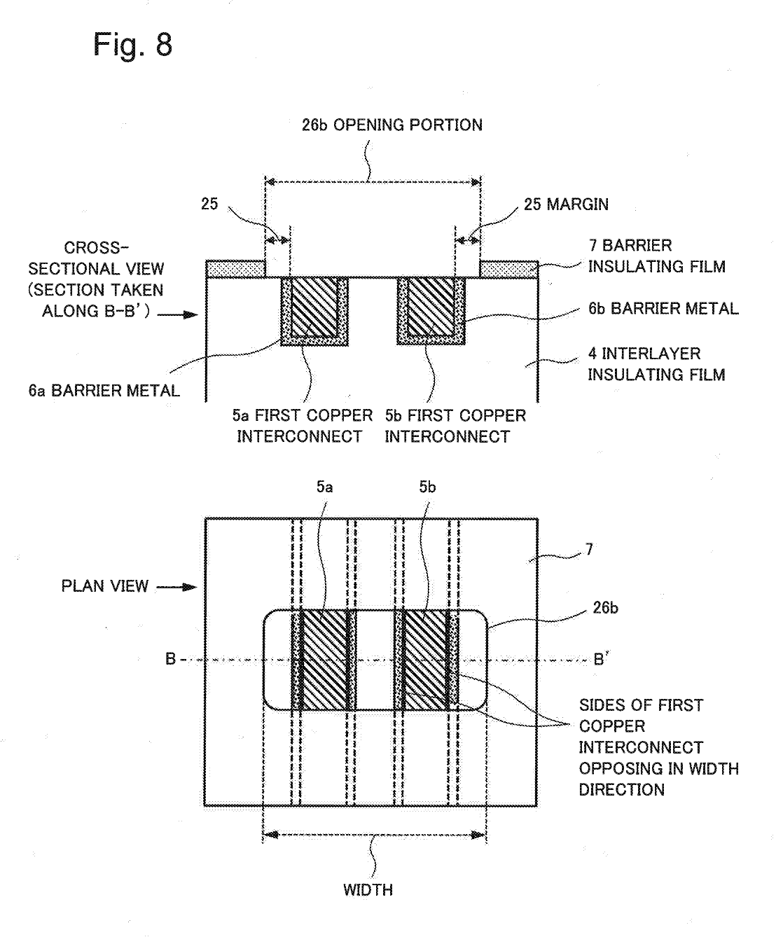

FIG. 8 illustrates a cross-sectional view (section taken along the line B-B′) and a plan view for explaining a position where the barrier insulating film 7 and an opening portion 26b are formed. Part of the barrier insulating film 7 that covers the first copper interconnects 5a and 5b and the interlayer insulating film 4 are removed by etching to provide the opening portion 26b. The opening portion 26b is provided so as to expose part of the upper surfaces of the first copper interconnects 5a and 5b including both sides thereof opposing each other in a width direction of each of the first copper interconnects 5a and 5b. At this time, the width of the opening portion 26b is larger than the width of the upper surfaces of the first copper interconnects 5a and 5b aligned side by side. Furthermore, the opening portion 26b is provided so that ends of the opening portion 26b have a margin 25 from the ends of the upper surface of the first copper interconnects 5a and 5b in a width direction that the ends of the opening portion 26a oppose. With the provision of the margin 25, even though the position of the opening portion 26b is shifted, the surface area of the exposed upper surfaces of the first copper interconnects 5a and 5b may be maintained constant.

If corners of the opening portion 26b are rounded in the actual manufacturing steps, the margin 25 may be set to a size considering the roundness.

In the variable-resistance element 1b of the present example embodiment, two variable-resistance elements are formed by a combination of the first copper interconnect 5a-the variable-resistance film 9-the upper electrode 10, and a combination of the first copper interconnect 5b-the variable-resistance element 9-the upper electrode 10, and a complementary type switch (CAS) having the common upper electrode 10 is achieved.

The variable-resistance element 1b of the present example embodiment may be fabricated by using the material and the manufacturing method of the second example embodiment.

The semiconductor device of the present example embodiment is a semiconductor device which includes the variable-resistance element 1b integrated therein. In other words, the variable-resistance element 1b is built in a multilayer copper interconnect of a semiconductor integrated circuit such as the programmable logic including a semiconductor element and the like such as a transistor formed on a silicon substrate by using the semiconductor manufacturing steps and having a multilayer copper interconnect. The semiconductor device may additionally have a package that protects the semiconductor integrated circuit.

According to the present example embodiment, a metal disposition type variable-resistance element in which variations in program voltage and leak current in a high-resistant state are reduced while reducing the program voltage may be manufactured with high yield.

### Fourth Example Embodiment

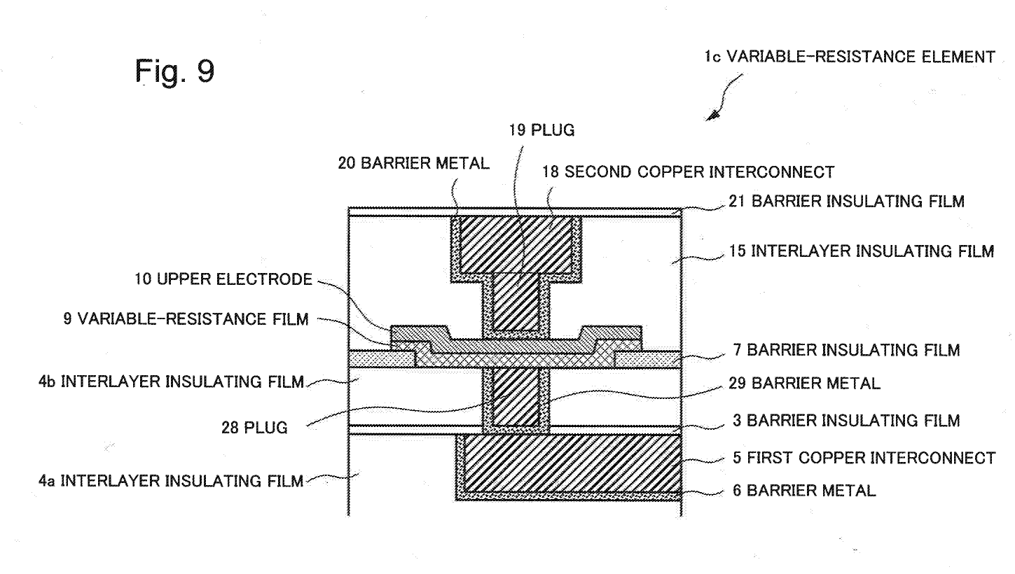

FIG. 9 is a cross-sectional view illustrating a structure of a variable-resistance element according to a fourth example embodiment of the present invention. A variable-resistance element 1c of the present example embodiment includes a plug 28 which corresponds to an electrode that supplies a metal ion to the variable-resistance film 9, the barrier insulating film 7, the variable-resistance film 9, and the upper electrode 10, which is the inert electrode that does not supply a metal ion to the variable-resistance film 9.

The first copper interconnect 5 in the multilayer copper interconnect of the semiconductor integrated circuit is covered with the barrier metal 6 over the side surface and the bottom surface, and is embedded in an interlayer insulating film 4a. Part of the upper surface of the first copper interconnect 5 is connected to the plug 28 via an opening portion of a barrier insulating film 3. The plug 28 is covered with a barrier metal 29 over side surfaces and a bottom surface and is embedded in an interlayer insulating film 4b. The plug 28 is in contact with the variable-resistance film 9 via the opening portion formed in the barrier insulating layer 7.

The variable-resistance film 9 is in contact with the upper electrode 10. The upper electrode 10 is connected to the plug 19 covered with the barrier metal 20. The plug 19 is connected to the second copper interconnect 18. The side surfaces and a portion of the bottom surface, which is not in contact with the plug 19, of the second copper interconnect 18 are covered with the barrier metal 20. The second copper interconnect 18, the plug 19, the upper electrode 10, and the variable-resistance film 9 are embedded in the interlayer insulating film 15, and the interlayer insulating film 15 and the second copper interconnect 18 are covered with the barrier insulating film 21.

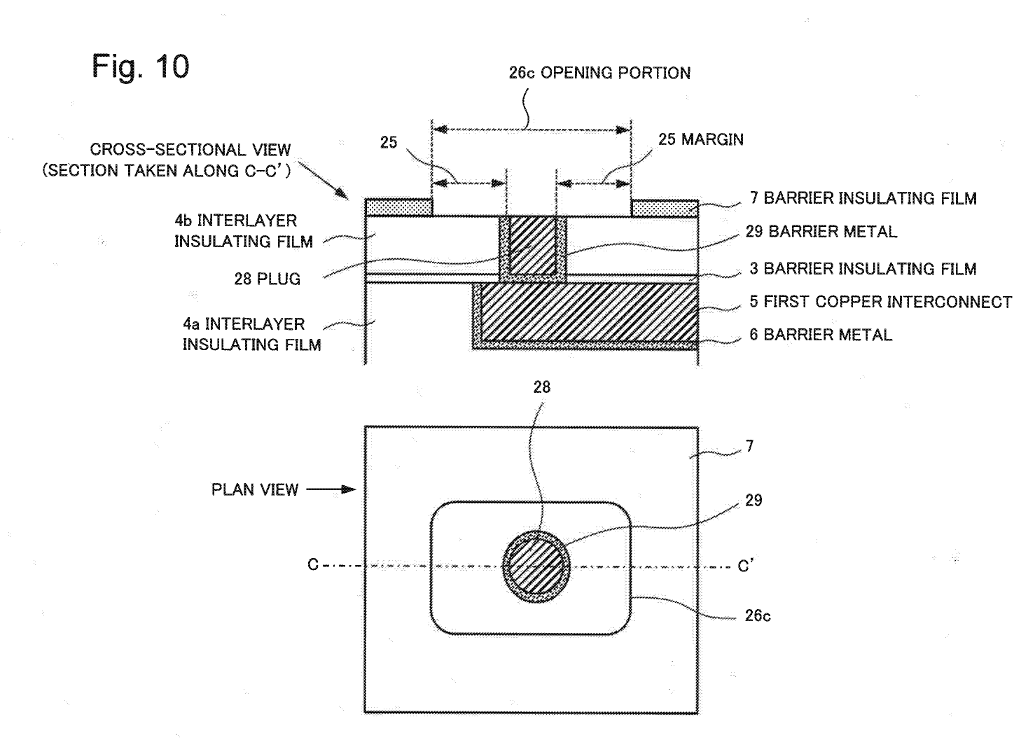

FIG. 10 illustrates a cross-sectional view (section taken along the line C-C′) and a plan view for explaining a position of formation of an opening portion 26c. Part of the barrier insulating film 7 that covers an upper surface of the plug 28 and the interlayer insulating film 4b are removed by etching to provide the opening portion 26c. The opening portion 26c is provided so that the upper surface of the plug 28 is entirely exposed. At this time, the width of the opening portion 26c is larger than the width of the upper surface of the plug 28. In addition, the opening portion 26c is provided so that ends of the opening portion 26c have a margin 25 from ends of the upper surface of the plug 28 that the ends of the opening portion 26c oppose. With the provision of the margin 25, even though the position of the opening portion 26c is shifted, the surface area of the exposed upper surface of the plug 28 may be maintained constant.

The margin 25 in FIG. 10 may be provided in a direction perpendicular to a width direction of the opening portion 26c illustrated in FIG. 10. If corners of the opening portion 26c are rounded in the actual manufacturing steps, the margin 25 may be set to a size considering the roundness.

The structure of the variable-resistance element 1c is achieved by using the following materials.

The interlayer insulating films 4a, 4b, and 15 are formed on a substrate (illustration is omitted) including a semiconductor device and the like such as a transistor formed on a silicon substrate by using the semiconductor manufacturing steps. The interlayer insulating film 4a, the interlayer insulating film 4b, and the interlayer insulating film 15 may be formed of a compound of silicon and oxygen and, more preferably, are formed of a low-dielectric constant insulating film formed by adding a given amount of hydrogen, fluorine, or carbon to a compound of silicon and oxygen.

The barrier insulating film 3, the barrier insulating film 7, and the barrier insulating film 21 are formed on the interlayer insulating film 4a, the interlayer insulating film 4b, and the interlayer insulating film 15 including the first copper interconnect 5, the plug 28, and the second copper interconnect 18, respectively. The barrier insulating films have not only an effect of preventing oxidation of copper contained in the copper interconnect and the plug, but also an effect of preventing the copper from diffusing into the interlayer insulating film during and after manufacture. For example, silicon carbide, silicon carbonitride, or silicon nitride, or a laminated structure thereof may be used as the barrier insulating films.

The barrier metal 6, the barrier metal 20, and the barrier metal 29 may be, for example, tantalum nitride or tantalum, or a laminated structure thereof. The thickness of tantalum nitride or tantalum may be on the order of 5 to 30 nm. The barrier metals have an effect of preventing copper in the copper interconnect and the plug from diffusing into the interlayer insulating film.

The material of the plug 28 is a metal that is capable of supplying a metal ion into the variable-resistance film 9, and preferably is copper because copper is widely used as the interconnect material of the integrated circuit. Preferably, the material of the first copper interconnect 5, the plug 19, and the second copper interconnect 18 is copper.

The variable-resistance film 9 may be oxidized materials such as tantalum oxide or titanium oxide or calcogenide materials such as copper sulfide and silver sulfide. The switching element for programmable logic is preferably formed of the above-described oxidized material, specifically, tantalum oxide. The reason why the oxidized material is suitable is that the voltage at the time of switching is higher than the logic voltage. In addition, the reason why tantalum oxide is preferable is that the tantalum oxide is highly reliable because the durable number of times of switching is 1000 times or more. The thickness of the variable-resistance film 9, which is an ion conducting layer, is preferably on the order of 5 nm to 20 nm. The thickness of 5 nm or smaller causes a leak current when the power is OFF due to a tunnel current or a Schottky current. In contrast, the thickness of 20 nm or larger increases the switching voltage to 10V or higher, so that the required voltage is increased.

A metal which is less likely to be diffused or conduct an ion in the variable-resistance film 9 is used for the upper electrode 10. The upper electrode 10 is preferably formed of a metallic material having a smaller free energy of oxidation in absolute value than a metal component in the variable-resistance film 9 (for example, tantalum). For example, ruthenium, platinum, or ruthenium alloy may be used for the upper electrode 10.

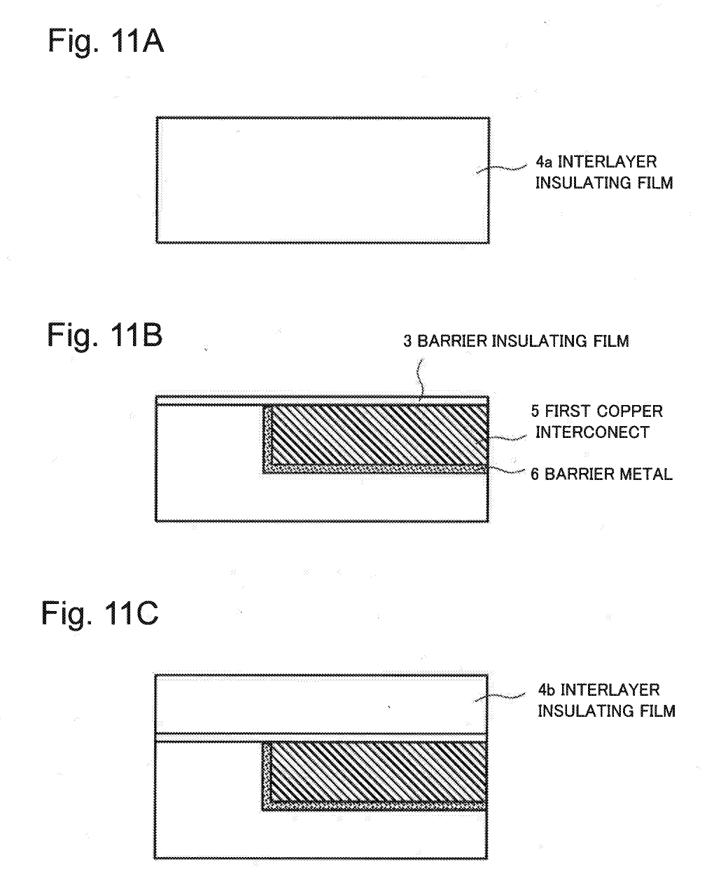

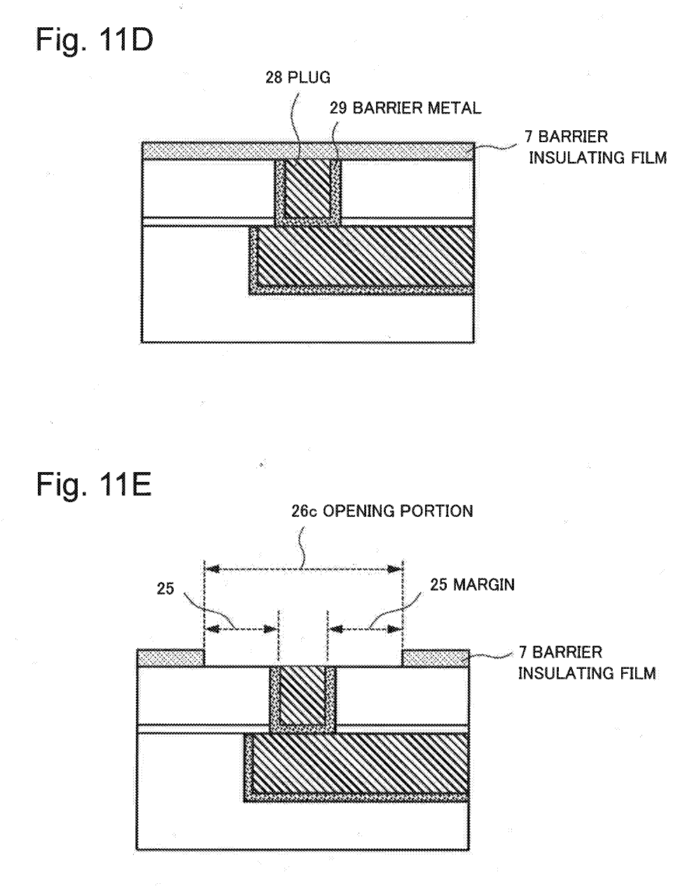

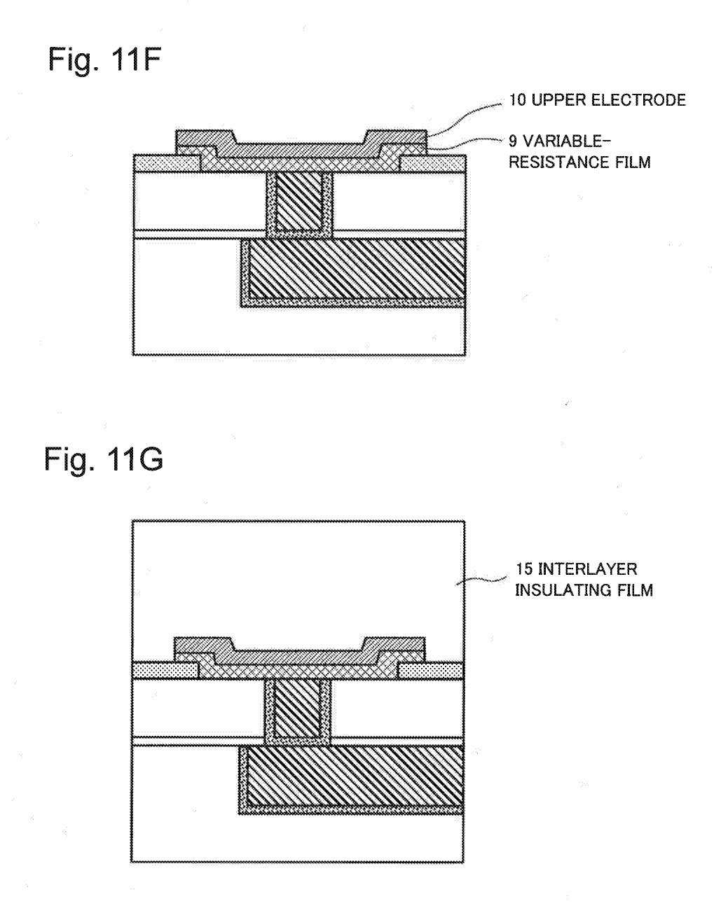

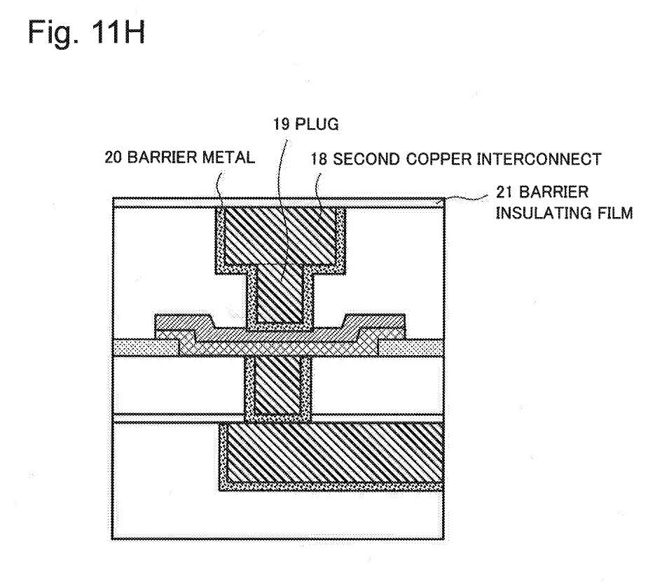

The structure of the variable-resistance element 1c may be fabricated by the following manufacturing steps (FIG. 11A to FIG. 11H).

[Step 1] (Forming Interlayer Insulating Film: FIG. 11A) A substrate (illustration is omitted) including a semiconductor device and the like such as a transistor formed on a silicon substrate by using the semiconductor manufacturing steps is prepared. A silicon nitride film is formed on the substrate as the interlayer insulating films 4a by the CVD method.

[Step 2] (Forming Interconnect: FIG. 11B) An opening portion where the first copper interconnect 5 is to be embedded is formed in the interlayer insulating film 4a by using photolithography technique and etching technique. The barrier metal 6 and a copper seed layer are formed in the formed opening portion by the CVD method. The barrier metal 6 may be tantalum nitride having a thickness of 10 nm. The copper seed layer has a thickness on the order of 10 nm to 100 nm, and a small amount of impurity, for example, aluminum is added to be contained therein. Subsequently, electrolytic plating of copper is performed on the copper seed layer. The thickness of copper may be on the order of 800 nm to 1200 nm. Subsequently, useless part of the barrier metal and the copper outside of the opening portion is removed away by the CMP method.

Next, silicon carbonitride having a thickness of 50 nm is formed as the barrier insulating film 3 that covers the interlayer insulating film 4a, the first copper interconnect 5, and the barrier metal 6 by a sputtering method or the CVD method. Next, thermal treatment is performed to cause the impurity in the copper seed layer to be diffused over the entire part of the first copper interconnect 5. By the thermal treatment, electromigration resistance of the first copper interconnect 5 is improved.

[Step 3] (Forming Interlayer Insulating Film: FIG. 11C) A silicon oxide film which corresponds to the interlayer insulating film 4b is formed by the CVD method.

[Step 4] (Forming Plug: FIG. 11D) An opening portion where the plug 28 is to be embedded is formed in the interlayer insulating film 4b by using the photolithography technique and the etching technique. The barrier metal 29 and a copper seed layer are formed in the formed opening portion by the CVD method. The barrier metal 29 may be tantalum nitride having a thickness of 10 nm. The thickness of the copper seed layer may be on the order of 10 nm to 100 nm. Subsequently, the copper plating is performed on the copper seed layer. The thickness of the copper may be on the order of 400 nm to 600 nm. Subsequently, useless part of the barrier metal and the copper outside of the opening portion is removed away by the CMP method to form the plug 28. Next, silicon carbonitride having a thickness of 50 nm is formed as the barrier insulating film 7 that covers the interlayer insulating film 4b, the plug 28, and the barrier metal 29 by the sputtering method or the CVD method.

[Step 5] (Opening Barrier Insulating Film: FIG. 11E) The opening portion 26c of the barrier insulating film 7 is formed by using the photolithography technique and the etching technique. The opening portion 26c is formed so that the upper surface of the plug 28 is entirely exposed. At this time, the width of the opening portion 26c is larger than the width of the upper surface of the plug 28. In addition, the opening portion 26c is provided so that ends of the opening portion 26c have a margin 25 from the ends of the upper surface of the plug 28 that the ends of the opening portion 26c oppose. With the provision of the margin 25, even though the position of the opening portion 26c is shifted, the surface area of the exposed upper surface of the plug 28 may be maintained constant, and thus the manufacturing yield may be increased.

Causes of the positional shift of the opening portion 26c involve accuracy of photolithography when determining the position of the opening portion 26c. Therefore, the margin 25 is preferably set at least to a range within which the accuracy of the photolithography is ensured. As used herein the term “accuracy of photolithography” is intended to include accuracy of registration of an exposing machine such as a stepper. If corners of the opening portion 26c are rounded in the manufacturing steps, the margin 25 may be set to a size considering the roundness.

[Step 6] (Forming Variable-Resistance Film and Upper Electrode: FIG. 11F) Tantalum oxide having a thickness of 15 nm is formed as the variable-resistance film 9 and ruthenium having a thickness of 50 nm is formed as the upper electrode 10 by the sputtering method or the CVD method. By using the photolithography technique and the etching technique, the variable-resistance film 9 and the upper electrode 10 are processed into a shape that covers the opening portion 26a and also covers part of the barrier insulating film 7.

[Step 7] (Forming Interlayer Insulating Film: FIG. 11G) A silicon oxide film is formed as the interlayer insulating film 15 by the CVD method. Here, a level difference exists on the surface of the silicon oxide film due to level differences of the variable-resistance film 9 and the upper electrode 10, the level difference is flattened by the CMP method. The thickness of the interlayer insulating film 15 may be on the order of 600 nm.

[Step 8] (Forming Connection Plug and Interconnect: FIG. 11H) An opening portion where the plug 19 and the second copper interconnect 18 are to be embedded is formed in the interlayer insulating film 15 by using the photolithography technique and the etching technique. The barrier metal 20 and the copper seed layer, which corresponds to part of the copper, are formed in the formed opening portion by the sputtering method or the CVD method. The barrier metal 6 may be tantalum nitride having a thickness of 10 nm. The thickness of the copper seed layer may be on the order of 10 nm to 100 nm. Subsequently, the copper plating is performed on the copper seed layer. The thickness of the copper may be on the order of 800 nm to 1200 nm. Subsequently, useless part of the barrier metal and the copper outside of the opening portion are removed away by the CMP method to form the plug 19 and the second copper interconnect 18. Next, silicon carbonitride having a thickness of 50 nm that corresponds to the barrier insulating film 21 is formed by the sputtering method or the CVD method.

In the manufacturing method described above, the material or the thickness of each layer may be changed in a various manner within a range that ensures the function as the variable-resistance element.

The semiconductor device of the present example embodiment is a semiconductor device which includes the variable-resistance element 1c integrated therein. In other words, the variable-resistance element 1c is built in a multilayer copper interconnect of a semiconductor integrated circuit such as the programmable logic including a semiconductor element and the like such as a transistor formed on a silicon substrate by using the semiconductor manufacturing steps and having a multilayer copper interconnect. The semiconductor device may additionally have a package that protects the semiconductor integrated circuit.

According to the present example embodiment, a metal disposition type variable-resistance element in which variations in program voltage and leak current in a high-resistant state are reduced while reducing the program voltage may be manufactured with high yield.

### Fifth Example Embodiment

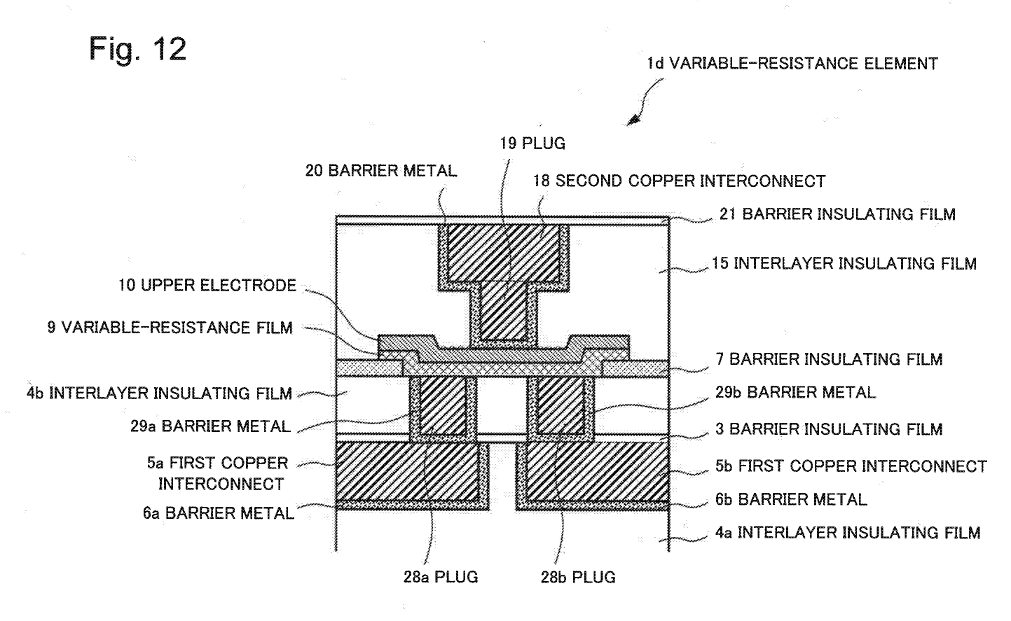

FIG. 12 is a cross-sectional view illustrating a structure of a variable-resistance element according to a fifth example embodiment of the present invention. A variable-resistance element 1d of the present example embodiment includes a plug 28a and a plug 28b which correspond to electrodes that supply a metal ion to the variable-resistance film 9, the barrier insulating film 7, the variable-resistance film 9, and the upper electrode 10, which is the inert electrode that does not supply a metal ion to the variable-resistance film 9.

The first copper interconnect 5a and the first copper interconnect 5b in the multilayer copper interconnect of the semiconductor integrated circuit are covered with a barrier metal 6a and a barrier metal 6b over the side surfaces and the bottom surfaces, respectively, and are embedded in the interlayer insulating film 4a. Part of the upper surface of the first copper interconnect 5a is connected to the plug 28a via the opening portion of the barrier insulating film 3. Part of the upper surface of the first copper interconnect 5b is connected to the plug 28b via the opening portion of the barrier insulating film 3. The plug 28a and the plug 28b are covered with a barrier metal 29a and a barrier metal 29b over side surfaces and bottom surfaces, respectively, and are embedded in the interlayer insulating film 4b. The plug 28a and the plug 28b are in contact with the variable-resistance film 9 via the opening portion formed in the barrier insulating layer 7.

The variable-resistance film 9 is in contact with the upper electrode 10. The upper electrode is connected to the plug 19 covered with the barrier metal 20. The plug 19 is connected to the second copper interconnect 18. The side surface and a portion of the bottom surface, which is not in contact with the plug 19, of the second copper interconnect 18 are covered with the barrier metal 20. The second copper interconnect 18, the plug 19, the upper electrode 10, and the variable-resistance film 9 are embedded in the interlayer insulating film 15, and the interlayer insulating film 15 and the second copper interconnect 18 are covered with the barrier insulating film 21.

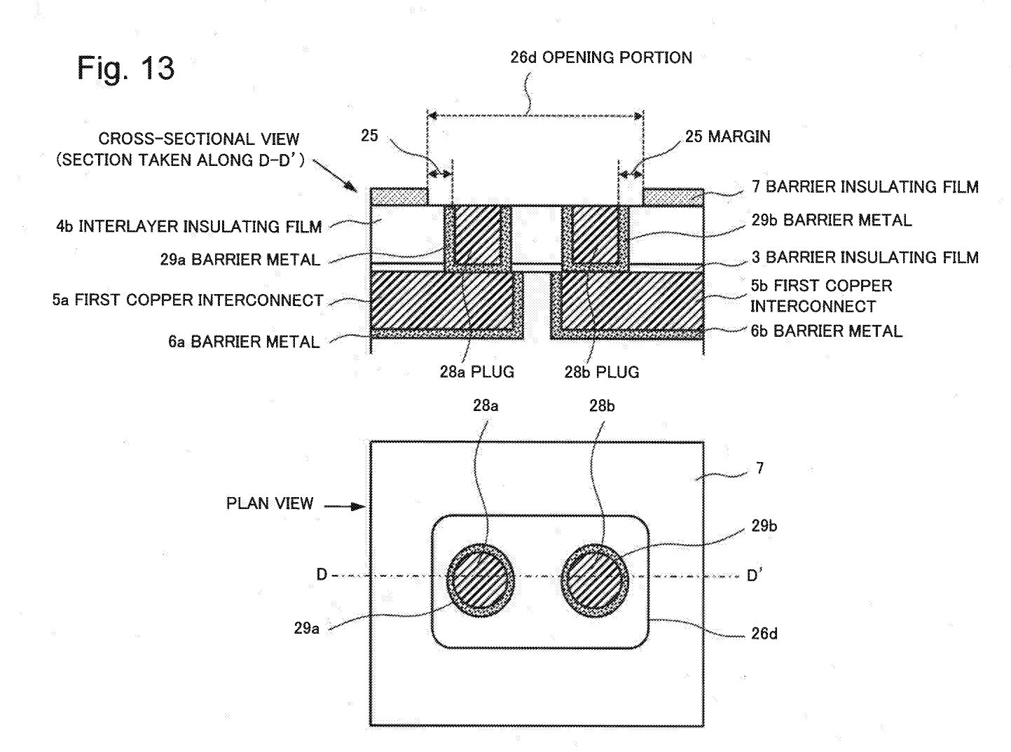

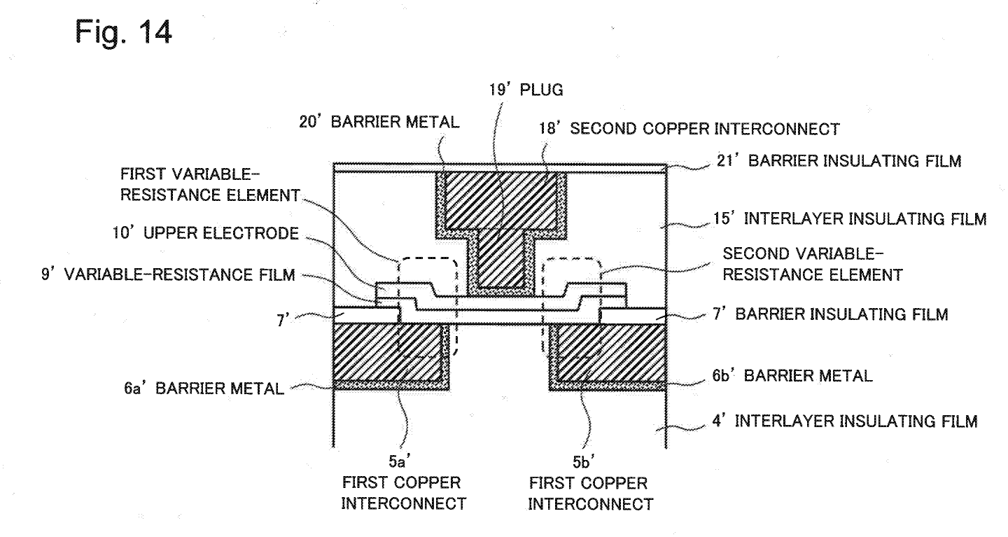

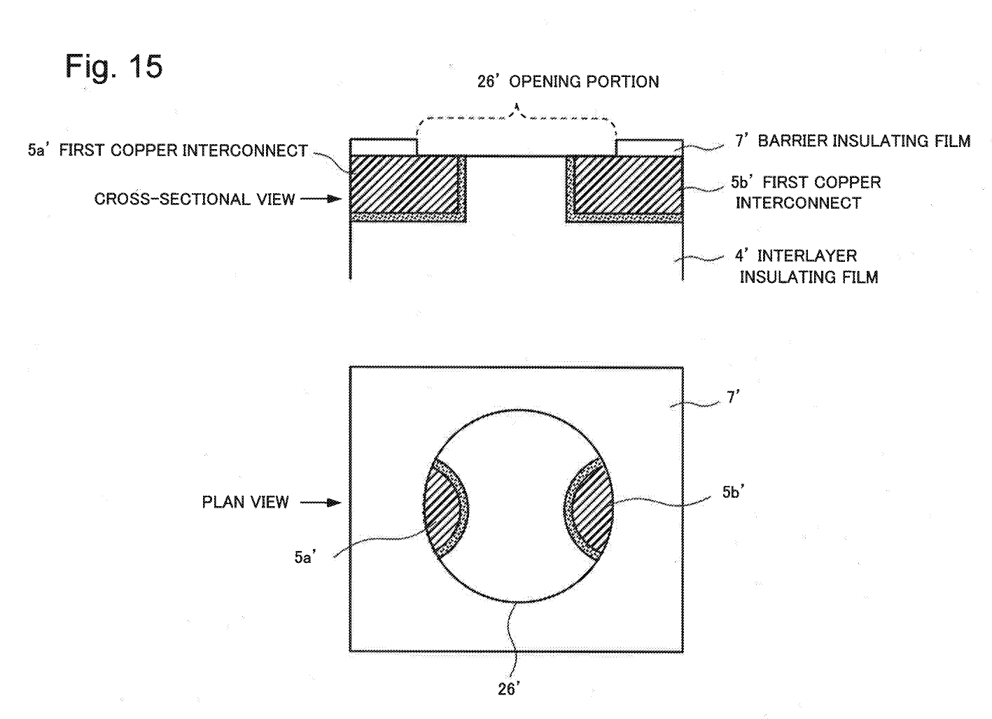

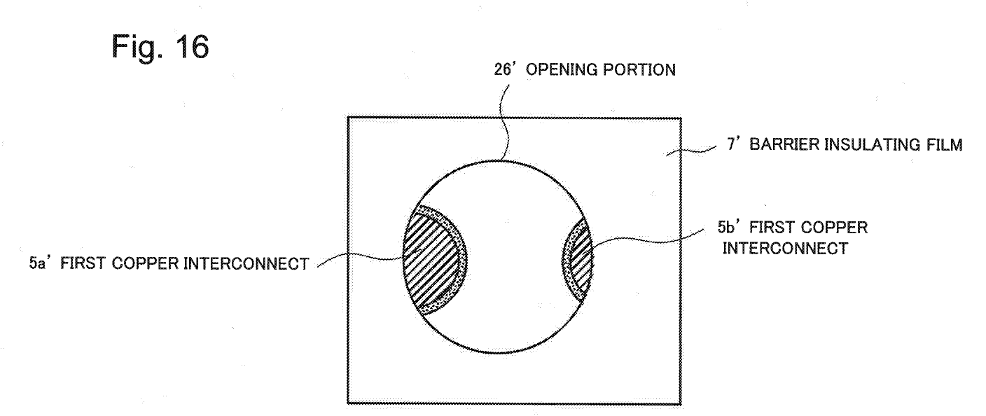

FIG. 13 illustrates a cross-sectional view (section taken along the line D-D′) and a plan view for explaining a position of formation of an opening portion 26d. Part of the barrier insulating film 7 that covers upper surfaces of the plug 28a and the plug 28b and the interlayer insulating film 4b are removed by etching to provide the opening portion 26d. The opening portion 26d is provided so that the upper surfaces of the plug 28a and the plug 28b are entirely exposed. In addition, the opening portion 26d is provided so that the ends of the opening portion 26d have a margin 25 from ends of the upper surfaces of the plug 28a and the plug 28b that the ends of the opening portion 26d oppose. With the provision of the margin 25, even though the position of the opening portion 26d is shifted, the surface areas of the exposed upper surfaces of the plug 28a and the plug 28b may be maintained constant.

The margin 25 in FIG. 13 may be provided in a direction perpendicular to a width direction of the opening portion 26d illustrated in FIG. 13. If corners of the opening portion 26d are rounded in the actual manufacturing steps, the margin 25 may be set to a size considering the roundness.

In the variable-resistance element 1d of the present example embodiment, two variable-resistance elements are formed by a combination of the plug 28a-the variable-resistance film 9-the upper electrode 10, and a combination of the plug 28b-the variable-resistance element 9-the upper electrode 10, and a complementary type switch (CAS) having the common upper electrode 10 is achieved.

The variable-resistance element 1d of the present example embodiment may be fabricated by using the material and the manufacturing method of the fourth example embodiment.

The semiconductor device of the present example embodiment is a semiconductor device which includes the variable-resistance element 1d integrated therein. In other words, the variable-resistance element 1d is built in a multilayer copper interconnect of a semiconductor integrated circuit such as the programmable logic including a semiconductor element and the like such as a transistor formed on a silicon substrate by using the semiconductor manufacturing steps and having a multilayer copper interconnect. The semiconductor device may additionally have a package that protects the semiconductor integrated circuit.

According to the present example embodiment, a metal disposition type variable-resistance element in which variations in program voltage and leak current in a high-resistant state are reduced while reducing the program voltage may be manufactured with high yield.

The present invention is not limited to the above-described example embodiments, and various modifications may be made within the scope of the invention described in Claims, and such modifications are included within the scope of the present invention.

The whole or part of the example embodiments disclosed above can be described as, but not limited to, the following supplementary notes.

### Supplementary Note

### (Supplementary Note 1)

A variable-resistance element including:

a first electrode that supplies a metal ion, the first electrode being embedded in a first insulating film and having an upper surface exposed from the first insulating film through an opening portion of a second insulating film, the second insulating film covering the first insulating film;

a metal disposition type variable-resistance film that covers the opening portion and comes into contact with an upper surface of the first electrode; and

a second electrode that comes into contact with an upper surface of the variable-resistance film, wherein the opening portion has a width larger than a width of the upper surface of the first electrode, and an end of the opening portion is provided with a margin from an end of the upper surface of the first electrode that the end of the opening portion opposes.

### (Supplementary Note 2)

The variable-resistance element according to Supplementary Note 1, wherein the first electrode includes a copper interconnect in a multilayer copper interconnect of a semiconductor integrated circuit, and the opening portion exposes part of an upper surface including both sides of the copper interconnect opposing in a width direction.

### (Supplementary Note 3)

The variable-resistance element according to Supplementary Note 1, wherein the first electrode includes a copper plug in a multilayer copper interconnect of a semiconductor integrated circuit, and the opening portion exposes the entire upper surface of the copper plug.

### (Supplementary Note 4)

The variable-resistance element according to any one of Supplementary Notes 1 to 3, wherein the opening portion exposes a side surface of the first electrode continuing from the upper surface of the first electrode.

### (Supplementary Note 5)

The variable-resistance element according to any one of Supplementary Notes 1 to 4, wherein a plurality of the first electrodes are provided.

### (Supplementary Note 6)

The variable-resistance element according to any one of Supplementary Notes 1 to 5, wherein the margin allows positional shift of the opening portion.

### (Supplementary Note 7)

The variable-resistance element according to any one of Supplementary Notes 1 to 6, wherein the margin is at least a range within which accuracy of photolithography is ensured.

### (Supplementary Note 8)

The variable-resistance element according to any one of Supplementary Notes 1 to 7, wherein the second electrode includes ruthenium or platinum.

### (Supplementary Note 9)

A method of manufacturing a variable-resistance element including: forming a first electrode that is embedded in a first insulating film and supplies a metal ion;

forming a second insulating film that covers the first insulating film and the first electrode;

forming an opening portion in the second insulating film so as to expose an upper surface of the first electrode, the opening portion having the width larger than the width of the upper surface of the first electrode, and an end of the opening portion having a margin from an end of the upper surface of the first electrode that the end of the opening portion opposes;

forming a metal disposition type variable-resistance film that covers the opening portion and comes into contact with the upper surface of the first electrode, and

forming a second electrode that comes into contact with an upper surface of the variable-resistance film.

### (Supplementary Note 10)

The method of manufacturing a variable-resistance element according to Supplementary Note 9, wherein the first electrode includes a copper interconnect in a multilayer copper interconnect of a semiconductor integrated circuit, and the opening portion exposes part of the upper surface including both sides of the copper interconnect opposing in the width direction.

### (Supplementary Note 11)

The method of manufacturing a variable-resistance element according to Supplementary Note 9, wherein the first electrode includes a copper plug in the multilayer copper interconnect of the semiconductor integrated circuit, and the opening portion exposes an upper surface of the copper plug entirely.

### (Supplementary Note 12)

The method of manufacturing a variable-resistance element according to any one of Supplementary Notes 9 to 11, wherein the opening portion exposes a side surface of the first electrode continuing from the upper surface of the first electrode.

### (Supplementary Note 13)

The method of manufacturing a variable-resistance element according to any one of Supplementary Notes 9 to 12, wherein a plurality of the first electrodes are provided.

### (Supplementary Note 14)

The method of manufacturing a variable-resistance element according to any one of Supplementary Notes 9 to 13, wherein the margin allows positional shift of the opening portion.

### (Supplementary Note 15)

The method of manufacturing a variable-resistance element according to any one of Supplementary Notes 9 to 14, wherein the margin is at least a range within which accuracy of photolithography is ensured.

### (Supplementary Note 16)

The method of manufacturing a variable-resistance element according to any one of second electrodes 9 to 15, wherein the second electrode includes ruthenium or platinum.

### (Supplementary Note 17)

A semiconductor device including the variable-resistance element according to any one of Supplementary Notes 1 to 8 built into a multilayer copper interconnect of a semiconductor integrated circuit that has the multilayer copper interconnect.

This application is based upon and claims the benefit of priority from Japanese patent application No. 2014-237452, filed on Nov. 25, 2014, the disclosure of which is incorporated herein in its entirety by reference.

### INDUSTRIAL APPLICABILITY

The present invention is applicable to semiconductor devices, specifically to programmable devices and memories which are semiconductor devices using a metal disposition type variable-resistance element.

### REFERENCE SIGNS LIST

1, 1a, 1b, 1c, 1d variable-resistance element
2 semiconductor device
3, 7, 7′, 21, 21′ barrier insulating film
4, 4′, 4a, 4b, 15, 15′ interlayer insulating film
5, 5a, 5b, 5a′, 5b′ first copper interconnect
6, 6a, 6b, 6b′, 20, 20′, 29, 29a, 29b barrier metal
9, 9′ variable-resistance film
10, 10′ upper electrode
18, 18′ second copper interconnect
19, 19′, 28, 28a, 28b plug
25 margin
26a, 26b, 26c, 26d, 26′ opening portion
27 overetched portion
30 semiconductor integrated circuit
101 first insulating film
102 second insulating film
103 opening portion
104 first electrode
105 variable-resistance film
106 second electrode
107 margin

What is claimed is:

1. A variable-resistance element including:
a first electrode that supplies a metal ion, the first electrode being embedded in a first insulating film and having an upper surface exposed from the first insulating film through an opening portion of a second insulating film, the second insulating film covering the first insulating film;
a metal disposition type variable-resistance film that covers the opening portion and comes into contact with an upper surface of the first electrode; and
a second electrode that comes into contact with an upper surface of the variable-resistance film, wherein
the opening portion has a width larger than a width of the upper surface of the first electrode, and
an end of the opening portion is provided with a margin from an end of the upper surface of the first electrode that the end of the opening portion opposes.

2. The variable-resistance element according to claim 1, wherein the first electrode includes a copper interconnect in a multilayer copper interconnect of a semiconductor integrated circuit, and the opening portion exposes part of an upper surface including both sides of the copper interconnect opposing in a width direction.

3. The variable-resistance element according to claim 1, wherein the first electrode includes a copper plug in a multilayer copper interconnect of a semiconductor integrated circuit, and the opening portion exposes the entire upper surface of the copper plug.

4. The variable-resistance element according to claim 1, wherein the opening portion exposes a side surface of the first electrode continuing from the upper surface of the first electrode.

5. The variable-resistance element according to claim 1, wherein a plurality of the first electrodes are provided.

6. The variable-resistance element according to claim 1, wherein the margin allows positional shift of the opening portion.

7. A method of manufacturing a variable-resistance element including:
forming a first electrode that is embedded in a first insulating film and supplies a metal ion;
forming a second insulating film that covers the first insulating film and the first electrode;
forming an opening portion in the second insulating film so as to expose an upper surface of the first electrode, the opening portion having the width larger than the width of the upper surface of the first electrode, and an end of the opening portion having a margin from an end of the upper surface of the first electrode that the end of the opening portion opposes;
forming a metal disposition type variable-resistance film that covers the opening portion and comes into contact with the upper surface of the first electrode, and
forming a second electrode that comes into contact with an upper surface of the variable-resistance film.

8. The method of manufacturing a variable-resistance element according to claim 7, wherein the first electrode includes a copper interconnect in a multilayer copper interconnect of a semiconductor integrated circuit, and the opening portion exposes part of the upper surface including both sides of the copper interconnect opposing in the width direction.

9. The method of manufacturing a variable-resistance element according to claim 7, wherein the first electrode includes a copper plug in the multilayer copper interconnect of the semiconductor integrated circuit, and the opening portion exposes an upper surface of the copper plug entirely.

10. A semiconductor device including the variable-resistance element according to claim 1 built into a multilayer copper interconnect of a semiconductor integrated circuit that has the multilayer copper interconnect.
